(19) United States
(12) Patent Application Publication
(10) Pub. No.: US 2016/0240820 A1
(43) Pub. Date: Aug. 18, 2016

(54) Organic Light-Emitting Diode Device and Method for Producing Same

(71) Applicant: EverDisplay Optronics (Shanghai) Limited, Shanghai (CN)

(72) Inventors: Zhijiang He, Shanghai (CN); Yanpin Gao, Shanghai (CN)

(73) Assignee: EverDisplay Optronics (Shanghai) Limited

(21) Appl. No.: 15/042,943

(22) Filed: Feb. 12, 2016

(30) Foreign Application Priority Data
Feb. 16, 2015 (CN) 201510084650.3

(51) Int. Cl. H01L 51/52; H01L 51/56; H01L 51/50

(52) U.S. Cl. CPC H01L 51/5275; H01L 51/5271; H01L 51/5088; H01L 51/56; H01L 2251/53

(57) ABSTRACT

An organic light-emitting diode device includes an optical structure and an electrical structure. The optical structure includes a cavity length adjustment layer disposed on a reflective layer. The electrical structure includes an anode layer, a hole injection layer, a hole transport layer, a luminescent layer, an electron transport layer, and a cathode layer, which are disposed on the cavity length adjustment layer in sequence. The anode layer is electrically connected to the reflective layer. A method for producing an organic light-emitting diode device includes disposing a cavity length adjustment layer on a reflective layer to form an optical structure. An anode layer, a hole injection layer, a hole transport layer, a luminescent layer, an electron transport layer, and a cathode layer are disposed on the cavity length adjustment layer in sequence to form an electrical structure. The anode layer is electrically connected to the reflective layer.

### BACKGROUND OF THE INVENTION

The present invention relates to the display field and, more particularly, to an organic light-emitting diode device and a method for producing the organic light-emitting diode device.

Organic light-emitting diodes (also known as organic electroluminescence) include the features of self-illumination and use a very thin coating of organic material and a very thin glass substrate. The organic material emits light when electric current passes through.

Conventional organic light-emitting didoes (OLEDs) use top emission and adjust the chromaticity and the light intensity of the color emitted by the display panel through adjustment of the microcavity structure, obtaining a better chromaticity coordinate value. FIG. 1 shows a conventional OLED device structure. A first hole injection layer (HTL1), a second hole injection layer (HTL2), a third hole injection layer (HTL3), a hole transport layer (HTL), an emissive layer (EML), an electron transport layer (ETL) are formed on an anode substrate in sequence. Next, a cathode layer is deposited, and a light extraction layer is finally added. Adjustment of the microcavity structure is generally conducted by adjusting the thickness of the organic layer in the OLED device to adjust the thickness of one or more layers, which, in turn, adjust the cavity length, such that the optical length can be changed to obtain the spectrum with the desired chromaticity parameters. However, such an adjustment approach has disadvantages. Specifically, since the organic material has a low carrier mobility, the driving voltage of the OLED device changes when the thickness of the organic material changes, such that the electrical properties of the device also change, which results in difficulties in adjustment of the performances of the device. In a case that the cavity length is adjusted by adjusting the thickness of only one layer, the number of the holes and electrons of the OLED device also change, leading to imbalance and degradation of the efficiency of the device.

### BRIEF SUMMARY OF THE INVENTION

An objective of the present invention is to overcome the disadvantages of the conventional technology by providing an organic light-emitting diode device and a method for producing the organic light-emitting diode device, such that the problem of degradation of the efficiency of the device resulting from the change in the electrical properties during adjustment of the optical length of the conventional device can be solved.

The technical solution for achieving the above objective is an organic light-emitting diode device according to the present invention including an optical structure and an electrical structure. The optical structure includes a reflective layer and a cavity length adjustment layer disposed on the reflective layer. The electrical structure includes an anode layer, a hole injection layer, a hole transport layer, a luminescent layer, an electron transport layer, and a cathode layer. The anode layer, the hole injection layer, the hole transport layer, the luminescent layer, the electron transport layer, and the cathode layer are disposed on the cavity length adjustment layer in sequence. The anode layer is electrically connected to the reflective layer.

By using the separate design of the optical structure and the electrical structure, adjustment of the optical length of the device can be achieved by simply adjusting the thickness of the cavity length adjustment layer of the optical structure without affecting the properties of the electrical structure. Thus, the problem of degradation of the efficiency of the device resulting from the change of the electrical properties during adjustment of the optical length in the conventional technology can be solved.

The cavity length adjustment layer can have a thickness matching an optical length of the light outputted by the organic light-emitting diode device.

The anode layer can cover the cavity length adjustment layer and can have a portion formed on the reflective layer.

The electrical structure can further include a light extraction layer disposed on the cathode layer.

The reflective layer can include a first indium tin oxide layer, a silver layer, and a second indium tin oxide layer. The silver layer is sandwiched between the first and second indium tin oxide layers.

A method for producing an organic light-emitting diode device according to the present invention includes:
preparing a reflective layer and disposing a cavity length adjustment layer on the reflective layer to form an optical structure; and
disposing an anode layer, a hole injection layer, a hole transport layer, a luminescent layer, an electron transport layer, and a cathode layer on the cavity length adjustment layer in sequence to form an electrical structure, wherein the anode layer is electrically connected to the reflective layer.

By using the separate design of the optical structure and the electrical structure, adjustment of the optical length of the device can be achieved by simply adjusting the thickness of the cavity length adjustment layer of the optical structure without affecting the properties of the electrical structure. Thus, the problem of degradation of the efficiency of the device resulting from the change of the electrical properties during adjustment of the optical length in the conventional technology can be solved.

The cavity length adjustment layer has a thickness matching an optical length of the light outputted by the organic light-emitting diode device. Disposing the cavity length adjustment layer can include:
calculating the thickness of the cavity length adjustment layer according to the optical length of the light outputted by the organic light-emitting diode device; and
disposing the cavity length adjustment layer with the thickness on the reflective layer.

Disposing the anode layer can include using a mask having an opening larger than the cavity length adjustment layer to form the anode layer covering the cavity length adjustment layer, and a portion of the anode layer is formed on the reflective layer.

The method for producing an organic light-emitting diode device can further include disposing a light extraction layer on the cathode layer.

The reflective layer includes a first indium tin oxide layer, a silver layer, and a second indium tin oxide layer. Preparing the reflective layer can include: preparing the first indium tin layer, disposing the silver layer on the first indium tin layer, and disposing the second indium tin layer on the silver layer.

The present invention will become clearer in light of the following detailed description of illustrative embodiments of this invention described in connection with the drawings.

### DESCRIPTION OF THE DRAWINGS

FIG. 1 is a diagrammatic view of a conventional organic light-emitting diode device.

FIG. 2 is a diagrammatic view of an organic light-emitting diode device according to the present invention.

FIG. 3 is a diagram illustrating the light output efficiency of the conventional organic light-emitting diode device.

FIG. 4 is a diagram illustrating the light output efficiency of the organic light-emitting diode device according to the present invention.

FIG. 5 is a block diagram illustrating a method for producing an organic light-emitting diode device according to the present invention.

### DETAILED DESCRIPTION OF THE INVENTION

FIG. 2 is a diagrammatic view of an organic light-emitting diode device according to the present invention. The organic light-emitting diode device includes a separate design of an optical structure and an electrical structure. The electrical design includes a reflective layer and a cavity length adjustment layer. The electrical structure includes an anode connected to the reflective layer of the optical structure to provide current conduction between the optical structure and the electrical structure. By using the above design, adjustment of the optical length of the device can be achieved by adjusting the thickness of the cavity length adjustment layer, such that the device has a better optical effect and such that the optical properties of the device can be in the best status, Since the optical structure is separate from the electrical structure, the electrical properties of the device are not affected by the adjustment of the optical length, and the electrical structure can be adjusted to the best status, such that the organic light-emitting diode device has the best properties. The organic light-emitting diode device according to the present invention permits independent adjustment of the optical properties and the electrical properties without mutual interference. The organic light-emitting diode device according to the present invention will now be set forth in connection with the accompanying drawings.

With reference to FIG. 2, the organic light-emitting diode device according to the present invention includes an optical structure 10 and an electrical structure 20. The optical structure 10 includes a reflective layer 101 and a cavity length adjustment layer 102 disposed on the reflective layer 101. The electrical structure 20 includes an anode layer 201, a hole injection layer 202, a hole transport layer 203, a luminescent layer 204, an electron transport layer 205, and a cathode layer 206. The anode layer 201, the hole injection layer 202, the hole transport layer 203, the luminescent layer 204, the electron transport layer 205, and the cathode layer 206 are disposed on the cavity length adjustment layer 102 in sequence. The anode layer 201 is electrically connected to the reflective layer 101 to provide current conduction between the optical structure 10 and the electrical structure 20. Due to the separate design of the optical structure 10 and the electrical structure 20, adjustment of the optical properties and adjustment of the electrical properties do not interference with each other. With regard to adjustment of the optical properties, the thickness of the cavity length adjustment layer 102 can be adjusted to adjust the optical length. Since the optical length is equal to the thickness of the cavity length adjustment layer 102 times the refractive index of the cavity length adjustment layer 102, adjustment of the optical length can be achieved by adjusting the thickness of the cavity length adjustment layer 102, such that the device can have better optical properties.

In a preferred example of the present invention, the cavity length adjustment layer 102 is an electron transport layer having a thickness matching the optical length of the light outputted by the organic light-emitting diode device. The thickness of the cavity length adjustment layer 102 can be determined by the set optical length of the outputted light (the optical length is equal to the thickness of the cavity length adjustment layer 102 times the refractive index of the cavity length adjustment layer 102). Different organic light-emitting diode devices correspond to cavity length adjustment layers 102 of different thicknesses, and each cavity length adjustment layer 102 has an optical thickness value. When the cavity length adjustment layer 102 has an optimal thickness value, the corresponding organic light-emitting diode device has the best optical properties.

The anode layer 201 of the electrical structure 20 is made of silver (Ag). The cathode 206 is made of Mg—Ag alloy. Adjustment of the electrical properties of the organic light-emitting diode device can be conducted by adjusting the work function of the cathode or the anode, the highest occupied molecular orbital (HOMO), and the lowest unoccupied molecular orbital (LUMO). Furthermore, the electrical properties of the device can achieve the best status by adjusting the thicknesses of the organic layers and the parameters related to the electronics.

In a preferred example of the present invention, the cavity length adjustment layer 102 of the optical structure 10 has an area smaller than an area of the reflective layer 101. The anode layer 201 of the electrical structure 20 covers the cavity length adjustment layer 102 and has a portion formed on the reflective layer 101 to provide electrical connection between the electrical structure 20 and the optical structure 10. The reflective layer 101 includes a first indium tin oxide (ITO) layer, a silver (Ag) layer, and a second indium tin oxide (ITO) layer. The silver (Ag) layer is sandwiched between the first and second indium tin oxide (ITO) layers. In a preferred example of the present invention, the electrical structure 20 further includes a light extraction layer 207 disposed on the cathode layer 206 to further improve the light output efficiency of the organic light-emitting diode device.

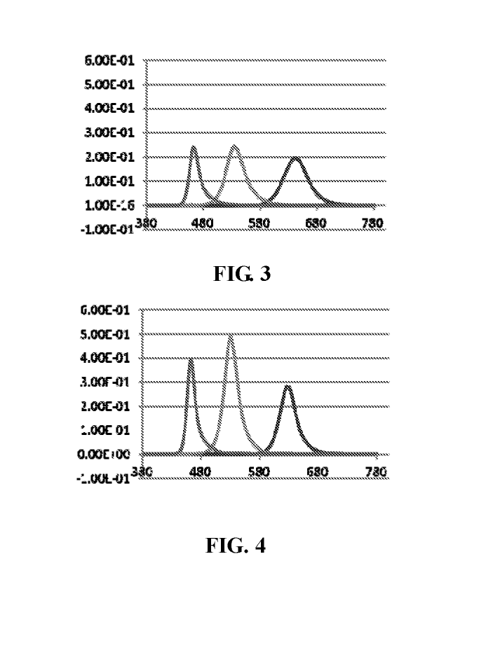

FIG. 3 is a diagram illustrating the light output efficiency of the conventional organic light-emitting diode device. FIG. 4 is a diagram illustrating the light output efficiency of the organic light-emitting diode device according to the present invention. The light output effect of the organic light-emitting diode device will now be set forth in connection with FIGS. 3 and 4.

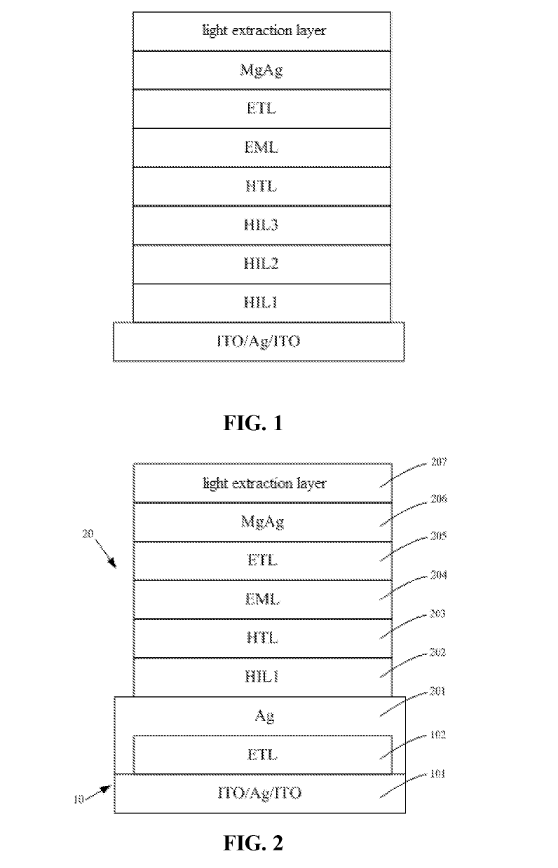

As shown in FIGS. 3 and 4, the light output efficiency of the organic light-emitting diode device according to the present invention is obviously higher than the light output efficiency of the conventional organic light-emitting diode device. Specifically, the organic light-emitting diode device according to the present invention adopts the separate design of the optical structure 10 and the electrical structure 20, wherein adjustment of the electrical properties of the optical structure 10 does not affect the electrical properties of the electrical structure 20 (namely, adjustments of the properties of the optical structure 10 and the electrical structure 20 do not interfere with each other). Thus, comparing the electrical structure 20 with the conventional structure of FIG. 1, a couple of hole injection layers can be omitted, such that the overall thickness of the electrical structure 20 is reduced. Thus, the driving voltage of the device is reduced, reducing the power consumption of the device, improving the efficiency of the device, and prolong the service life of the device.

The advantageous effects of the organic light-emitting diode device according to the present invention are that by using the separate design of the optical structure 10 and the electrical structure 20, adjustments of the electrical properties and the optical properties of the device can be achieved independently without mutual interference, such that the electrical properties and the optical properties of the whole device can achieve the best status. Thus, the problem of degradation of the efficiency of the device resulting from the change in the electrical properties during adjustment of the optical length of the conventional device can be solved.

The adjustment difficulties of the device can be reduced, because the electrical properties are not affected during adjustment of the optical properties.

Since the electrical structure 20 is independent, the thickness of the electrical structure 20 of the device can be thinner than that of the conventional device, such that the driving voltage of the device is reduced, increasing the efficiency of the device, prolonging the service life of the device, and reducing the power consumption of the device.

In actual use, the optical effects and the chromatic saturation of the device are obviously increased, and the color shift problem is effectively mitigated.

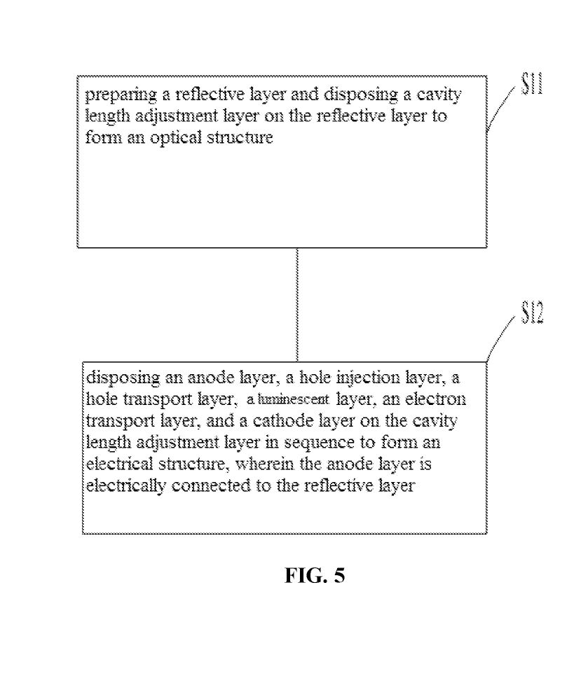

FIG. 5 is a block diagram illustrating a method for producing an organic light-emitting diode device according to the present invention. The method for producing an organic light-emitting diode device according to the present invention will now be set forth in connection with FIG. 5.

As shown in FIG. 5, the method for producing an organic light-emitting diode device according to the present invention includes:

Step S11: Preparing a reflective layer 101 and disposing a cavity length adjustment layer 102 on the reflective layer 101 to form an optical structure 10. With reference to FIG. 2, regarding disposition of the cavity length adjustment layer 102 on the reflective layer 101, the thickness of the cavity length adjustment layer 102 can be calculated according to the desired optical length (the optical length is equal to the thickness of the cavity length adjustment layer 102 times the refractive index of the cavity length adjustment layer 102). Namely, the thickness of the cavity length adjustment layer 102 can be calculated according to the desired optical effect. Different optical effects are obtained from different devices. Thus, the cavity length adjustment layer 102 has a different thickness according to the different device, and each of the different devices has an optimal value. Step S12 is then carried out.

Step S12: Disposing an anode layer 201, a hole injection layer 202, a hole transport layer 203, a luminescent layer 204, an electron transport layer 205, and a cathode layer 206 on the cavity length adjustment layer 102 in sequence to form an electrical structure 20. The anode layer 201 is electrically connected to the reflective layer 101. Specifically, the anode layer 201 is disposed on the cavity length adjustment layer 102 and serves as an anode of the electrical structure 20. The anode layer 201 is made of sliver (Ag). The anode layer 201 is connected to the reflective layer 101 to provide electrical connection between the optical structure 10 and the electrical structure 20. In a preferred example of the present invention, disposition of the anode layer 201 includes using a mask having an opening larger than the cavity length adjustment layer 102 to form the anode layer 201 covering the cavity length adjustment layer 102, and a portion of the anode layer 201 is formed on the reflective layer 101 to provide electrical connection between the optical structure 10 and the electrical structure 20. Next, the hole injection layer 202 is disposed on the anode layer 201, the hole transport layer 203 is disposed on the hole injection layer 202, the luminescent layer 204 is disposed on the hole transport layer 203, the electron transport layer 205 is disposed on the luminescent layer 204, and the cathode layer 206 is disposed on the electron transport layer 205. The cathode layer 206 is made of Mg—Ag alloy. The reflective layer 101 includes a first indium tin oxide (ITO) layer, a silver (Ag) layer, and a second indium tin oxide (ITO) layer. The silver layer is disposed between the first and second indium tin oxide (ITO) layers. Preparation of the reflective layer 101 includes preparing the first indium tin layer, disposing the silver layer on the first indium tin layer, and disposing the second indium tin layer on the silver layer.

The method for producing an organic light-emitting diode device according to the present invention can further include disposing a light extraction layer 207 on the cathode layer 206 to improve the light output efficiency of the organic light-emitting diode device.

Formation or preparation of each organic layer includes deposition, printing, stamping, or spin coating.

The advantageous effects of the method for producing an organic light-emitting diode device according to the present invention are that the thickness of the cavity length adjustment layer 102 can be adjusted during disposition to achieve adjustment of the optical properties of the device while reducing the adjustment difficulties of the device without affecting the electrical properties of the device.

By using the separate design of the optical structure 10 and the electrical structure 20, adjustments of the electrical properties and the optical properties of the device can be achieved independently without mutual interference, such that the electrical properties and the optical properties of the whole device can achieve the best status. Thus, the degradation of the efficiency of the device resulting from the change in the electrical properties during adjustment of the optical length of the conventional device can be solved.

Since the electrical structure 20 is independent, the thickness of the electrical structure 20 of the device can be thinner than that of the conventional device, such that the driving voltage of the device is reduced, increasing the efficiency of the device, prolonging the service life of the device, and reducing the power consumption of the device.

In actual use, the optical effects and the chromatic saturation of the device are obviously increased, and the color shift problem is effectively mitigated.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. An organic light-emitting diode device comprising an optical structure and an electrical structure, with the optical structure including a reflective layer and a cavity length adjustment layer disposed on the reflective layer, with the electrical structure including an anode layer, a hole injection layer, a hole transport layer, an luminescent layer, an electron transport layer, and a cathode layer, with the anode layer, the hole injection layer, the hole transport layer, the luminescent layer, the electron transport layer, and the cathode layer disposed on the cavity length adjustment layer in sequence, and with the anode layer electrically connected to the reflective layer.

2. The organic light-emitting diode device according to claim 1, wherein the cavity length adjustment layer has a thickness determined by the refractive index of the cavity length adjustment layer and an optical length of light outputted by the organic light-emitting diode device.

3. The organic light-emitting diode device according to claim 1, wherein the anode layer covers the cavity length adjustment layer and has a portion formed on the reflective layer.

4. The organic light-emitting diode device according to claim 2, wherein the electrical structure further includes a light extraction layer disposed on the cathode layer.

5. The organic light-emitting diode device according to claim 4, wherein the reflective layer includes a first indium tin oxide layer, a silver layer, and a second indium tin oxide layer, and wherein the silver layer is sandwiched between the first and second indium tin oxide layers.

6. A method for producing an organic light-emitting diode device, comprising:
preparing a reflective layer and disposing a cavity length adjustment layer on the reflective layer to form an optical structure; and
disposing an anode layer, a hole injection layer, a hole transport layer, a luminescent layer, an electron transport layer, and a cathode layer on the cavity length adjustment layer in sequence to form an electrical structure, wherein the anode layer is electrically connected to the reflective layer.

7. The method for producing an organic light-emitting diode device according to claim 6, wherein the cavity length adjustment layer has a thickness matching an optical length of light outputted by the organic light-emitting diode device, and wherein disposing the cavity length adjustment layer includes:
calculating the thickness of the cavity length adjustment layer according to the optical length of the light outputted by the organic light-emitting diode device; and
disposing the cavity length adjustment layer with the thickness on the reflective layer.

8. The method for producing an organic light-emitting diode device according to claim 6, wherein disposing the anode layer includes using a mask having an opening larger than the cavity length adjustment layer to form the anode layer covering the cavity length adjustment layer, and wherein a portion of the anode layer is formed on the reflective layer.

9. The method for producing an organic light-emitting diode device according to claim 6, further comprising disposing a light extraction layer on the cathode layer.

10. The method for producing an organic light-emitting diode device according to claim 6, wherein the reflective layer includes a first indium tin oxide layer, a silver layer, and a second indium tin oxide layer, and wherein preparing the reflective layer includes: preparing the first indium tin layer, disposing the silver layer on the first indium tin layer, and disposing the second indium tin layer on the silver layer.

11. An organic light-emitting diode device comprising an optical structure and an electrical structure, wherein the optical structure comprises a reflective layer and a cavity length adjustment layer disposed on the reflective layer, and the electrical structure is disposed on the cavity length adjustment layer and electrically connected to the reflective layer.

12. The organic light-emitting diode device according to claim 11, wherein the reflective layer comprises a first indium tin oxide layer, a silver layer, and a second indium tin oxide layer, the silver layer is sandwiched between the first and second indium tin oxide layers, and the cavity length adjustment layer is contacted with either the first indium tin oxide layer or the second indium tin oxide layer.

13. The organic light-emitting diode device according to claim 11, wherein the electrical structure comprises an anode layer, and the anode layer is disposed on the cavity length adjustment layer of the optical structure.

14. The organic light-emitting diode device according to claim 13, wherein the electrical connection is between the anode layer of the electrical structure and the reflective layer.

15. The organic light-emitting diode device according to claim 13, wherein the electrical structure further comprises a hole injection layer, a hole transport layer, an luminescent layer, an electron transport layer, and a cathode layer sequentially formed on the anode layer.

16. The organic light-emitting diode device according to claim 15, wherein the anode layer contacts with partial surface of the reflective layer.

17. The organic light-emitting diode device according to claim 17, wherein the reflective layer comprises a first indium tin oxide layer, a second indium tin oxide layer, and a silver layer sandwiched between the first and second indium tin oxide layers, and the anode layer contacts with partial surface of either the first indium tin oxide layer or the second indium tin oxide layer.

18. The organic light-emitting diode device according to claim 15, wherein the electrical structure further comprises a light extraction layer disposed on the cathode layer.
